(19) United States
(12) Patent Application Publication
(10) Pub. No.: US 2015/0340988 A1
(43) Pub. Date: Nov. 26, 2015

(54) CONCENTRATOR PHOTOVOLTAIC SYSTEM; SEMICONDUCTOR INTEGRATED CIRCUIT, TRACKING DEVIATION DETECTION PROGRAM, AND TRACKING DEVIATION CORRECTION PROGRAM TO BE USED IN THE CONCENTRATOR PHOTOVOLTAIC SYSTEM, AND TRACKING DEVIATION DETECTION METHOD AND TRACKING DEVIATION CORRECTION METHOD

(71) Applicant: Sumitomo Electric Industries, Ltd., Osaka-shi (JP)

(72) Inventors: Shinjirou SHINADA, Osaka-shi (JP); Seiji YAMAMOTO, Osaka-shi (JP); Naoki AYAI, Osaka-shi (JP); Takashi IWASAKI, Osaka-shi (JP); Hideaki NAKAHATA, Osaka-shi (JP)

(21) Appl. No.: 14/717,033

(22) Filed: May 20, 2015

(30) Foreign Application Priority Data
May 23, 2014 (JP) 2014-106726

(51) Int. Cl. H02S 20/32; H02S 40/22; H01L 31/054; H02S 40/30

(52) U.S. Cl. CPC H02S 20/32; H02S 40/30; H02S 40/22; H01L 31/0543

(57) ABSTRACT

This concentrator photovoltaic system includes: a concentrator photovoltaic panel; a driving device configured to cause the concentrator photovoltaic panel to perform periodical tracking operation with respect to the sun in two axes of azimuth and elevation; a measurement section configured to detect generated power or generated current as an amount of generated electricity of the concentrator photovoltaic panel; and a control section configured to obtain, when the driving device has caused the concentrator photovoltaic panel to perform tracking operation in either one of the two axes, a change in the amount of generated electricity of the concentrator photovoltaic panel before and after the tracking operation, the control section configured to determine presence/absence of tracking deviation that should be corrected, based on the change.

### TECHNICAL FIELD

The present invention relates to concentrator photovoltaic (CPV) for generating power by concentrating sunlight on a power generating element.

### BACKGROUND ART

In concentrator photovoltaic, a basic unit configuration is used in which sunlight concentrated by a lens is caused to be incident on a power generating element (solar cell) formed by a small-sized compound semiconductor having a high power generating efficiency. Specifically, for example, multiple Fresnel lenses formed from resin are arrayed vertically and horizontally on a transparent glass plate. Then, each of the Fresnel lenses concentrates sunlight, and the concentrated light is caused to be incident on its corresponding one of power generating elements which are arranged so as to correspond to the Fresnel lenses by the same number as that of the Fresnel lenses.

The power generating elements are arranged at equal intervals on an elongated flexible printed substrate, for example, and are connected to each other via a copper pattern. Further, a plurality of flexible printed circuits each having such power generating elements mounted thereon are arranged on a flat surface to be electrically connected to each other. In this manner, it is possible to collect outputs from the power generating elements by two-dimensionally arranging the power generating elements so as to correspond to the Fresnel lenses (for example, see PATENT LITERATURE 1 (FIGS. 1, 2, and 4), PATENT LITERATURE 2 (FIGS. 1, 2, 5, and 6), and PATENT LITERATURE 3 (FIGS. 1, 2, 5, and 6)).

When such a basic configuration is used as a concentrator photovoltaic module (for example, FIG. 2 of PATENT LITERATURE 1 to 3), by further arranging a plurality of the modules, a concentrator photovoltaic panel is formed (for example, FIG. 1 of PATENT LITERATURE 1 to 3). Then, a driving device causes the entirety of the concentrator photovoltaic panel to perform tracking operation so as to always face the sun, whereby a desired generated power can be obtained. Basically, the tracking operation relies on a tracking sensor and estimation of the position of the sun based on the time, the latitude, and the longitude of the installation place. It has also been proposed that installation error of the equipment is absorbed by means of software (for example, see PATENT LITERATURE 4).

### CITATION LIST

### Patent Literature

PATENT LITERATURE 1: Japanese Laid-Open Patent Publication No. 2013-80760
PATENT LITERATURE 2: Japanese Laid-Open Patent Publication No. 2013-93435
PATENT LITERATURE 3: Japanese Laid-Open Patent Publication No. 2013-93437
PATENT LITERATURE 4: Japanese Laid-Open Patent Publication No. 2009-186094

### SUMMARY OF INVENTION

### Technical Problem

However, the tracking sensor cannot be said as being completely free of errors, and may cause tracking deviation. Also, due to a long-term use, distortion occurring on the concentrator photovoltaic panel or the pedestal which supports the concentrator photovoltaic panel may cause tracking deviation.

Meanwhile, even when slight tracking deviation is occurring, as long as the deviation is not so large as to cause concentrated sunlight to be completely outside the power generating element, generated power can be obtained. Thus, occurrence of tracking deviation itself is difficult to be found. Moreover, how the deviation is occurring is not known from the appearance. Furthermore, under the environment where the sunshine condition can greatly change depending on the weather and clouds, it is not easy to detect tracking deviation.

In view of the above problems, an object of the present invention is to provide a technology of detecting at least deviation in tracking the sun in concentrator photovoltaic.

### Solution to Problem

<<Concentrator Photovoltaic System>>

A concentrator photovoltaic system includes: a concentrator photovoltaic panel; a driving device configured to cause the concentrator photovoltaic panel to perform periodical tracking operation with respect to the sun in two axes of azimuth and elevation; a measurement section configured to detect generated power or generated current as an amount of generated electricity of the concentrator photovoltaic panel; and a control section configured to obtain, when the driving device has caused the concentrator photovoltaic panel to perform tracking operation in either one of the two axes, a change in the amount of generated electricity of the concentrator photovoltaic panel before and after the tracking operation, the control section configured to determine presence/absence of tracking deviation that should be corrected, based on the change.

<<Semiconductor Integrated Circuit>>

The present invention is a semiconductor integrated circuit to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the semiconductor integrated circuit having a function of obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change.

<<Tracking Deviation Detection Program>>

The present invention is a tracking deviation detection program to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the tracking deviation detection program configured to cause a computer to realize a function of obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change.

<<Tracking Deviation Correction Program>>

The present invention is a tracking deviation correction program to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the tracking deviation correction program configured to cause a computer to realize: a function of obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change; and a function of determining, when having determined that there is tracking deviation that should be corrected, an axis and directionality in which the tracking deviation should be corrected, based on the axis in which the tracking operation has been performed, directionality of the tracking operation performed in the axis, and a sign of the change, and providing the driving device with an instruction to make correction in accordance with the determined axis and directionality in which the correction should be made.

<<Tracking Deviation Detection Method>>

A tracking deviation detection method of the present invention is a tracking deviation detection method performed by a control section provided in a photovoltaic system, the photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the tracking deviation detection method including: (i) obtaining, when the driving device has caused the concentrator photovoltaic panel to perform tracking operation in either one of the two axes, a change in the amount of generated electricity of the concentrator photovoltaic panel before and after the tracking operation; and (ii) determining presence/absence of tracking deviation that should be corrected, based on the change.

<<Tracking Deviation Correction Method>>

A tracking deviation correction method of the present invention is a tracking deviation correction method performed by a control section provided in a photovoltaic system, the photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the tracking deviation correction method including: (i) obtaining, when the driving device has caused the concentrator photovoltaic panel to perform tracking operation in either one of the two axes, a change in the amount of generated electricity of the concentrator photovoltaic panel before and after the tracking operation; (ii) determining presence/absence of tracking deviation that should be corrected, based on the change; (iii) determining, when having determined that there is tracking deviation that should be corrected, an axis and directionality in which the tracking deviation should be corrected, based on the axis in which the tracking operation has been performed, directionality of the tracking operation performed in the axis, and a sign of the change; and (iv) providing the driving device with an instruction to make correction in accordance with the axis and directionality in which the correction should be made.

### Advantageous Effects of Invention

According to the present invention, it is possible to easily and accurately determine whether there is tracking deviation that should be corrected in tracking of the sun performed in concentrator photovoltaic.

### BRIEF DESCRIPTION OF DRAWINGS

FIG. 1 is a perspective view showing one example of a concentrator photovoltaic apparatus;

FIG. 2 is a perspective view (partially cut out) showing an enlarged view of one example of a concentrator photovoltaic module;

FIG. 3 is an enlarged view of a portion III in FIG. 2;

FIG. 4 is a perspective view showing a state where, when the concentrator photovoltaic apparatus formed by arranging 64 (8 in length×8 in breadth) modules each having a substantially square shape is defined as “one unit”, 15 units are arranged in the premises;

FIG. 5 shows graphs of measured values of generated power of the 15 units of concentrator photovoltaic apparatuses at a time zone (11 o'clock to 12 o'clock) around the culmination time of the sun on one day;

FIG. 6 shows four graphs representing extracted characteristic change patterns of waveforms;

FIG. 7 shows the graph of pattern (a) and perspective charts each showing a position where a concentration spot is formed on a power generating element;

FIG. 8 shows the graph of pattern (b) and perspective charts each showing a position where the concentration spot is formed on the power generating element;

FIG. 9 shows the graph of pattern (c) and perspective charts each showing a position where the concentration spot is formed on the power generating element;

FIG. 10 shows the graph of pattern (d) and perspective charts each showing a position where the concentration spot is formed on the power generating element;

FIG. 11 is a block diagram showing one example of an electrical configuration for a concentrator photovoltaic system;

FIG. 12 is a flow chart (1/2) showing operation performed by a control section;

FIG. 13 is a flow chart (2/2) showing operation performed by the control section;

FIG. 14 shows one example of execution timings of MPPT control performed in a power conversion section and control regarding tracking deviation performed by the control section;

FIG. 15 shows one example of a semiconductor integrated circuit obtained by integrating the whole or a part of the control section on a semiconductor substrate;

FIG. 16 is a block diagram showing one example of an internal configuration of the semiconductor integrated circuit when an elevation upward direction drive signal is inputted thereto;

FIG. 17 is a block diagram showing one example of an internal configuration of the semiconductor integrated circuit when an elevation downward direction drive signal is inputted thereto;

FIG. 18 is a block diagram showing one example of an internal configuration of the semiconductor integrated circuit when an azimuth rightward direction drive signal is inputted thereto;

FIG. 19 is a block diagram showing one example of an internal configuration of the semiconductor integrated circuit when an azimuth leftward direction drive signal is inputted thereto;

FIG. 20 is a timing chart of operation performed by the semiconductor integrated circuit shown in FIG. 16;

FIG. 21 is a block diagram showing one example of an electrical configuration of the concentrator photovoltaic system according to a second embodiment;

FIG. 22 is a block diagram showing one example of an electrical configuration of the concentrator photovoltaic system according to a third embodiment; and

FIG. 23 is a graph showing the outline of change in generated power obtained through correction.

### DESCRIPTION OF EMBODIMENTS

### Summary of Embodiments

The summary of embodiments of the present invention includes at least the following.

(1) This concentrator photovoltaic system includes: a concentrator photovoltaic panel; a driving device configured to cause the concentrator photovoltaic panel to perform periodical tracking operation with respect to the sun in two axes of azimuth and elevation; a measurement section configured to detect generated power or generated current as an amount of generated electricity of the concentrator photovoltaic panel; and a control section configured to obtain, when the driving device has caused the concentrator photovoltaic panel to perform tracking operation in either one of the two axes, a change in the amount of generated electricity of the concentrator photovoltaic panel before and after the tracking operation, the control section configured to determine presence/absence of tracking deviation that should be corrected, based on the change.

In the concentrator photovoltaic system according to (1) above, based on the finding that the change in the amount of generated electricity before and after execution of tracking operation increases in accordance with increase of tracking deviation, it is possible to determine the presence/absence of tracking deviation that should be corrected. Since the amount of the change is that in the amount of generated electricity before and after tracking operation performed in a short time, it is less likely to be affected by the ambient brightness at that time. That is, irrespective of the state of solar radiation, it is possible to easily and accurately determine whether there is tracking deviation that should be corrected.

(2) In the concentrator photovoltaic system according to (1), when the driving device has caused the concentrator photovoltaic panel to perform tracking operation in either one of the two axes, the control section may obtain an amount of change in the amount of generated electricity of the concentrator photovoltaic panel before and after the tracking operation, and may determine presence/absence of tracking deviation that should be corrected, by comparing the amount of change with a predetermined threshold.

In this case, by comparing the amount of change with the threshold, it is possible to easily determine the presence/absence of tracking deviation that should be corrected.

(3) In the concentrator photovoltaic system according to (1) or (2), when the driving device has caused the tracking operation to be performed, in a case where the control section has determined that there is tracking deviation that should be corrected, the control section may determine an axis and directionality in which the tracking deviation should be corrected, based on the axis in which the tracking operation has been performed, directionality of the tracking operation performed in the axis, and a sign of the change, and may provide the driving device with an instruction to make correction by a predetermined amount in accordance with the determined axis and directionality in which the correction should be made.

In this case, it is possible to make correction for decreasing the deviation, with the axis and directionality (orientation) determined in which the tracking deviation should be corrected.

(4) In the concentrator photovoltaic system according to (2), when the driving device has caused the tracking operation to be performed, in a case where the control section has determined that there is tracking deviation that should be corrected, the control section may determine an axis and directionality in which the tracking deviation should be corrected, based on the axis in which the tracking operation has been performed, directionality of the tracking operation performed in the axis, and a sign of the change, and may provide the driving device with an instruction to make correction based on a correction amount which changes depending on a magnitude of an absolute value of the amount of change, in accordance with the determined axis and directionality in which the correction should be made.

In this case, faster correction can be performed.

(5) In the concentrator photovoltaic system according to (3) or (4), preferably, while correction of tracking deviation is being performed, the control section performs control such that detection and correction of another tracking deviation are not performed.

In this case, it is possible to assuredly execute the correction and then execute the next correction.

(6) In the concentrator photovoltaic system according to any one of (1) to (5), the driving device may provide the control section with real time information of drive start and drive stop with respect to the axis in which tracking operation is performed, and information about directionality of the tracking operation.

In this case, by comparing the amount of generated electricity at the time of drive start with the amount of generated electricity at the time of drive stop based on the real time information provided from the driving device, it is possible to accurately obtain the amount of change. Since the control section also obtains, from the driving device, information about the directionality of the axis in which tracking operation has been performed, the control section can obtain accurate information.

(7) In the concentrator photovoltaic system according to any one of (1) to (6), preferably, the control section and the measurement section are provided in a power converter configured to convert generated power of the concentrator photovoltaic panel into alternating current power.

In this case, an output from the concentrator photovoltaic panel is inputted to the power converter, and maximum power point tracking control is also performed therein. Thus, it is preferable to provide the measurement section in the power converter. Also, it is preferable to provide the control section which is relevant to the measurement section, in the same power converter.

(8) In the concentrator photovoltaic system according to (7), by utilizing a period between maximum power point tracking controls executed by the power converter in a constant cycle, the control section may execute operation regarding the tracking deviation.

In this case, it is after the immediately preceding maximum power point tracking control has ended that the control section performs processing regarding the tracking deviation. Thus, it is possible to more accurately measure the amount of generated electricity.

(9) In another viewpoint, this is a semiconductor integrated circuit to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the semiconductor integrated circuit having a function of obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change.

In the semiconductor integrated circuit according to (9) above, based on the finding that the amount of change in the amount of generated electricity before and after execution of tracking operation increases in accordance with increase of tracking deviation, it is possible to determine the presence/absence of tracking deviation that should be corrected. Since the amount of the change is that in the amount of generated electricity before and after tracking operation performed in a short time, it is less likely to be affected by the ambient brightness at that time. That is, irrespective of the state of solar radiation, it is possible to easily and accurately determine whether there is tracking deviation that should be corrected. In addition, necessary functions can be realized in a one-chip IC, for example, as a semiconductor integrated circuit. Thus, production of the concentrator photovoltaic system is facilitated. In addition, the semiconductor integrated circuit can be produced inexpensively.

(10) The semiconductor integrated circuit according to (9) may have a function of determining, when having determined that there is tracking deviation that should be corrected, an axis and directionality in which the tracking deviation should be corrected, based on the axis in which the tracking operation has been performed, directionality of the tracking operation performed in the axis, and a sign of the change, and providing the driving device with an instruction to make correction in accordance with the determined axis and directionality in which the correction should be made.

In this case, it is possible to make correction that decreases the deviation, with the axis and directionality (orientation) determined in which the tracking deviation should be corrected.

(11) In another viewpoint, this is a tracking deviation detection program to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the tracking deviation detection program configured to cause a computer to realize a function of obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change.

The tracking deviation detection program according to (11) above can realize necessary functions by being executed by a computer. That is, based on the finding that the amount of change in the amount of generated electricity before and after execution of tracking operation increases in accordance with increase of tracking deviation, it is possible to determine the presence/absence of tracking deviation that should be corrected. Since the amount of the change is that in the amount of generated electricity before and after tracking operation performed in a short time, it is less likely to be affected by the ambient brightness at that time. That is, irrespective of the state of solar radiation, it is possible to easily and accurately determine whether there is tracking deviation that should be corrected.

(12) In another viewpoint, this is a tracking deviation correction program to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the tracking deviation correction program configured to cause a computer to realize: a function of obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change; and a function of determining, when having determined that there is tracking deviation that should be corrected, an axis and directionality in which the tracking deviation should be corrected, based on the axis in which the tracking operation has been performed, directionality of the tracking operation performed in the axis, and a sign of the change, and providing the driving device with an instruction to make correction in accordance with the determined axis and directionality in which the correction should be made.

The tracking deviation correction program according to (12) above can realize necessary functions by being executed by a computer. That is, based on the finding that the amount of change in the amount of generated electricity before and after execution of tracking operation increases in accordance with increase of tracking deviation, it is possible to determine the presence/absence of tracking deviation that should be corrected. Since the amount of the change is that in the amount of generated electricity before and after tracking operation performed in a short time, it is less likely to be affected by the ambient brightness at that time. That is, irrespective of the state of solar radiation, it is possible to easily and accurately determine whether there is tracking deviation that should be corrected. Then, it is possible to make correction that decreases the deviation, with the axis and directionality (orientation) determined in which the tracking deviation should be corrected.

It should be noted that the programs according to (11) and (12) above can be recorded in a computer-readable recording medium.

In this case, since necessary functions are recorded in the recording medium, production of the concentrator photovoltaic system is facilitated, and in addition, such recording medium is easy to be distributed. Therefore, it is also easy to add the necessary functions to an existing concentrator photovoltaic system, and thus, it is also easy to upgrade the system.

(13) In another viewpoint, this is a tracking deviation detection method performed by a control section provided in a photovoltaic system, the photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the tracking deviation detection method including: (i) obtaining, when the driving device has caused the concentrator photovoltaic panel to perform tracking operation in either one of the two axes, a change in the amount of generated electricity of the concentrator photovoltaic panel before and after the tracking operation; and (ii) determining presence/absence of tracking deviation that should be corrected, based on the change.

In the tracking deviation detection method according to (13) above, based on the finding that the amount of change in the amount of generated electricity before and after execution of tracking operation increases in accordance with increase of tracking deviation, it is possible to determine the presence/absence of tracking deviation that should be corrected. Since the amount of the change is that in the amount of generated electricity before and after tracking operation performed in a short time, it is less likely to be affected by the ambient brightness at that time. That is, irrespective of the state of solar radiation, it is possible to easily and accurately determine whether there is tracking deviation that should be corrected.

(14) In another viewpoint, this is a tracking deviation correction method performed by a control section provided in a photovoltaic system, the photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel, the tracking deviation correction method including: (i) obtaining, when the driving device has caused the concentrator photovoltaic panel to perform tracking operation in either one of the two axes, a change in the amount of generated electricity of the concentrator photovoltaic panel before and after the tracking operation; (ii) determining presence/absence of tracking deviation that should be corrected, based on the change; (iii) determining, when having determined that there is tracking deviation that should be corrected, an axis and directionality in which the tracking deviation should be corrected, based on the axis in which the tracking operation has been performed, directionality of the tracking operation performed in the axis, and a sign of the change; and (iv) providing the driving device with an instruction to make correction in accordance with the axis and directionality in which the correction should be made.

In the tracking deviation correction method according to (14) above, based on the finding that the amount of change in the amount of generated electricity before and after execution of tracking operation increases in accordance with increase of tracking deviation, it is possible to determine the presence/absence of tracking deviation that should be corrected. Since the amount of the change is that in the amount of generated electricity before and after tracking operation performed in a short time, it is less likely to be affected by the ambient brightness at that time. That is, irrespective of the state of solar radiation, it is possible to easily and accurately determine whether there is tracking deviation that should be corrected. Then, it is possible to make correction that decreases the deviation, with the axis and directionality (orientation) determined in which the tracking deviation should be corrected.

### Details of Embodiments

Hereinafter, details of embodiments of the present invention will be described with reference to the drawings.

### First Embodiment

<<One Example of Concentrator Photovoltaic Apparatus>>

First, a structure of a concentrator photovoltaic apparatus will be described.

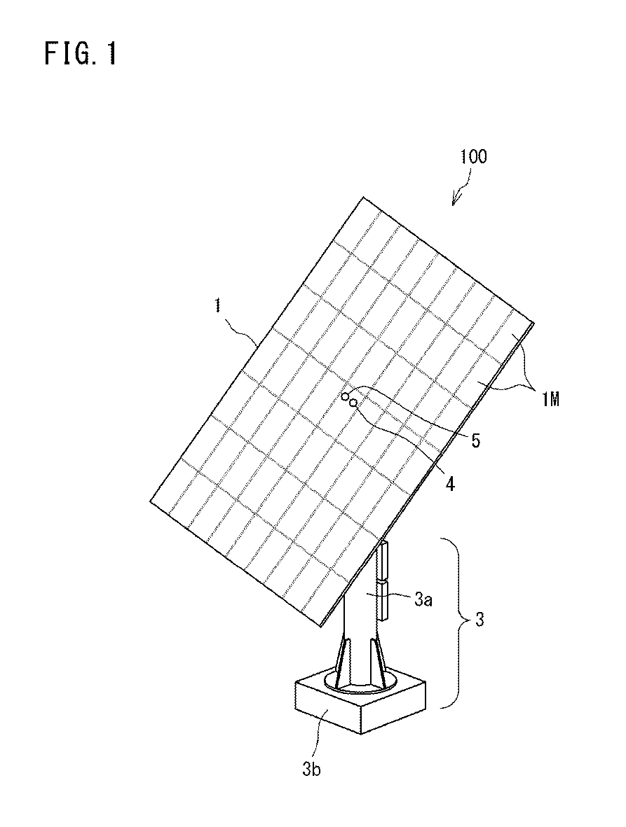

FIG. 1 is a perspective view showing one example of a concentrator photovoltaic apparatus. In the drawing, a concentrator photovoltaic apparatus 100 includes: a concentrator photovoltaic panel 1; and a pedestal 3 which includes a post 3a and a base 3b thereof, the post 3a supporting the concentrator photovoltaic panel 1 on the rear surface thereof. The concentrator photovoltaic panel 1 is formed by assembling multiple concentrator photovoltaic modules 1M vertically and horizontally. In this example, 62 (7 in length×9 in breadth−1) concentrator photovoltaic modules 1M are assembled vertically and horizontally, except the center portion. When one concentrator photovoltaic module 1M has a rated output of, for example, about 100 W, the entirety of the concentrator photovoltaic panel 1 has a rated output of about 6 kW.

On the rear surface side of the concentrator photovoltaic panel 1, a driving device (not shown) is provided, and by operating the driving device, it is possible to drive the concentrator photovoltaic panel 1 in two axes of the azimuth and the elevation. Specifically, the concentrator photovoltaic panel 1 is driven so as to always face the direction of the sun in both of the azimuth and the elevation, by use of stepping motors (not shown). At a place (in this example, the center portion) on the concentrator photovoltaic panel 1, or in the vicinity of the panel 1, a tracking sensor 4 and an actinometer 5 are provided. Operation of tracking the sun is performed, relying on the tracking sensor 4 and the position of the sun calculated from the time, the latitude, and the longitude of the installation place.

As the actinometer 5, there are a pyrheliometer and a pyranometer, for example. The pyrheliometer tracks the sun, together with the concentrator photovoltaic panel 1. As the pyranometer, there are a horizontal pyranometer and a normal pyranometer, for example. The horizontal pyranometer is not installed integrally with the concentrator photovoltaic panel 1, and is fixedly installed in the vicinity of the concentrator photovoltaic panel 1, for example. The horizontal pyranometer does not perform operation of tracking the sun. On the other hand, the normal pyranometer measures global light (direct light and diffuse light) received at a normal plane, and performs operation of tracking the sun, similarly to the concentrator photovoltaic panel 1. The normal pyranometer is installed on the concentrator photovoltaic panel 1 and performs tracking operation together with the concentrator photovoltaic panel 1, or installed in the vicinity of the concentrator photovoltaic panel 1 and performs tracking operation by itself

Every time the sun has moved by a predetermined angle, the driving device drives the concentrator photovoltaic panel 1 by the predetermined angle. The event that the sun has moved by the predetermined angle may be determined by the tracking sensor 4, or may be determined by the latitude, the longitude, and the time. Thus, there are also cases that the tracking sensor 4 is omitted. The predetermined angle is, for example, a constant value, but the value may be changed in accordance with the altitude of the sun and the time. Moreover, use of the stepping motors is one example, and other than this, a drive source capable of performing precise operation may be used.

<<One Example of Concentrator Photovoltaic Module>>

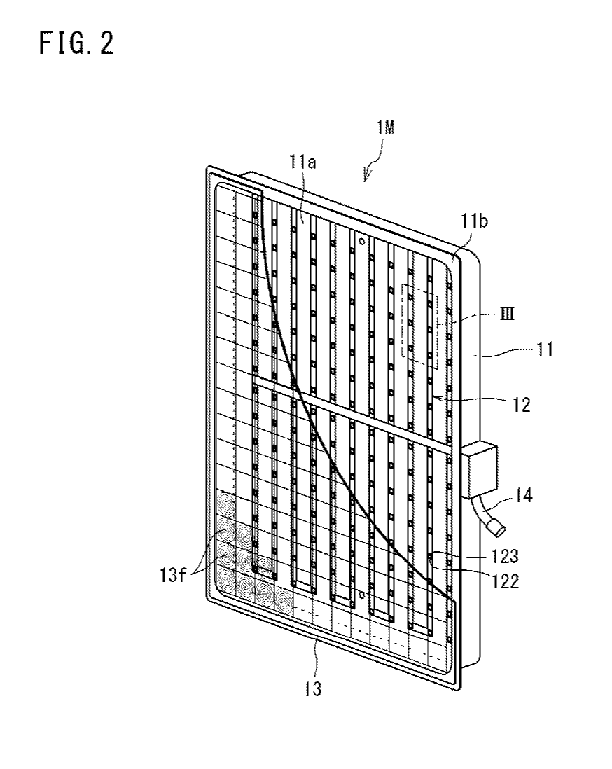

FIG. 2 is a perspective view (partially cut out) showing an enlarged view of one example of the concentrator photovoltaic module (hereinafter, also simply referred to as module) 1M. In the drawing, the module 1M includes: as main components, a housing 11 formed in a vessel shape (vat shape) and having a bottom surface 11a; a flexible printed circuit 12 provided in contact with the bottom surface 11a; and a primary concentrating portion 13 attached, like a cover, to a flange portion 11b of the housing 11. The housing 11 is made of metal.

The primary concentrating portion 13 is a Fresnel lens array and is formed by arranging, in a matrix shape, a plurality of (for example, 16 in length×12 in breadth, 192 in total) Fresnel lenses 13f as lens elements which concentrate sunlight. The primary concentrating portion 13 can be obtained by, for example, forming a silicone resin film on the back surface (inside) of a glass plate used as a base material. Each Fresnel lens is formed on this resin film. On the external surface of the housing 11, a connector 14 for taking out an output from the module 1M is provided.

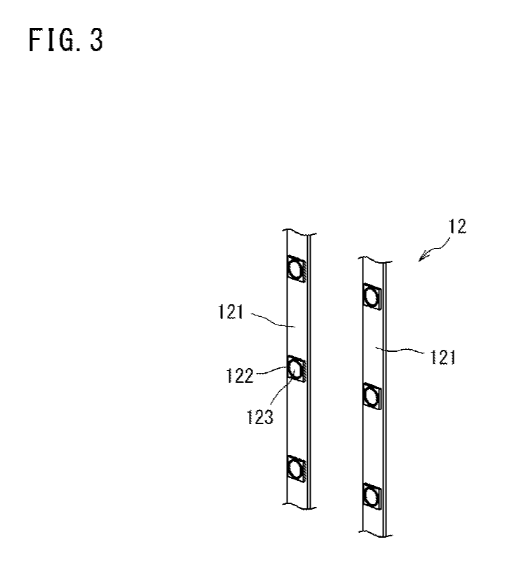

FIG. 3 is an enlarged view of a portion III in FIG. 2. In FIG. 3, the flexible printed circuit 12 includes: a flexible substrate 121 having a ribbon shape (strip shape); power generating elements (solar cells) 122 provided thereon; and secondary concentrating portions 123 respectively provided so as to cover the power generating elements 122. Sets of the power generating element 122 and the secondary concentrating portion 123 are provided at positions corresponding to the Fresnel lenses 13f of the primary concentrating portion 13, by the same number as that of the Fresnel lenses 13f. Each secondary concentrating portion 123 concentrates sunlight incident from its corresponding Fresnel lens 13f onto its corresponding power generating element 122. The secondary concentrating portion 123 is a lens, for example. However, the secondary concentrating portion 123 may be not a lens but a reflecting mirror that guides light downwardly while reflecting the light. Further, there are also cases where a secondary concentrating portion is not used. The power generating elements 122 are electrically connected in series-parallel by the flexible printed circuit 12, and the collected generated power is taken out through the connector 14 (FIG. 2).

It should be noted that the module 1M shown in FIG. 2 and FIG. 3 is merely one example, and there could be other various configurations of the module. For example, not the flexible printed substrate as above but multiple resin substrates or multiple ceramic substrates having a flat plate shape (rectangular shape or the like) may be used.

<<Installation Example of a Plurality of Units of Concentrator Photovoltaic Apparatuses>>

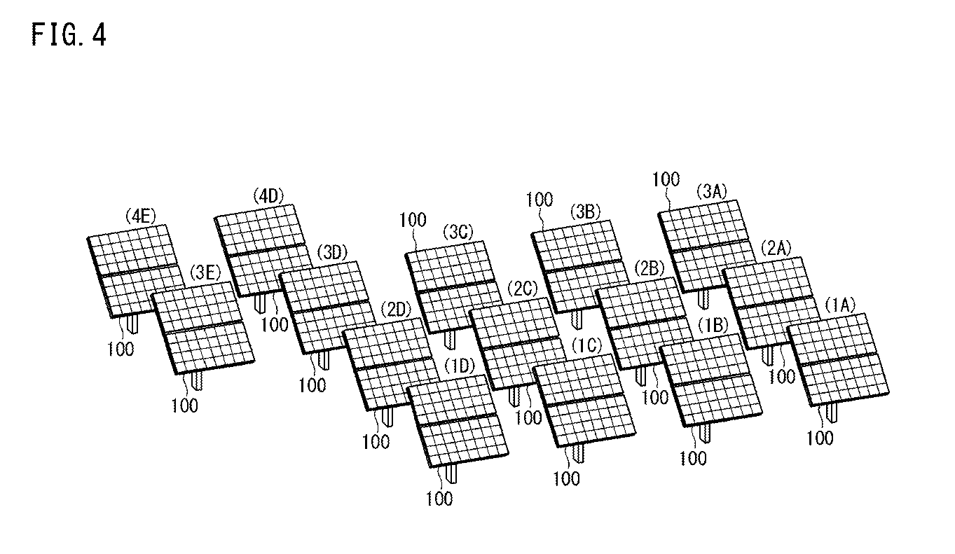

With regard to the concentrator photovoltaic apparatus 100 configured as above, the panel configuration (the number and arrangement of the modules 1M) can be freely changed as necessary. Also, the shape of the module can be rectangular, square, or a shape other than these. For example, FIG. 4 is a perspective view showing a state where, when the concentrator photovoltaic apparatus 100 formed by arranging 64 (8 in length×8 in breadth) modules each having a substantially square shape is defined as “one unit”, 15 units are arranged in the premises. Each unit is driven by its corresponding driving device (not shown) so as to track the sun. Here, 15 units of the concentrator photovoltaic apparatus 100 will be denoted by the following reference characters (also shown in FIG. 4) for convenience.

Four units in the front row: 1A, 1B, 1C, and 1D

Four units in the second row: 2A, 2B, 2C, and 2D

Five units in the third row: 3A, 3B, 3C, 3D, and 3E

Two units in the fourth row: 4D and 4E

<<Example of Temporal Change in Generated Power>>

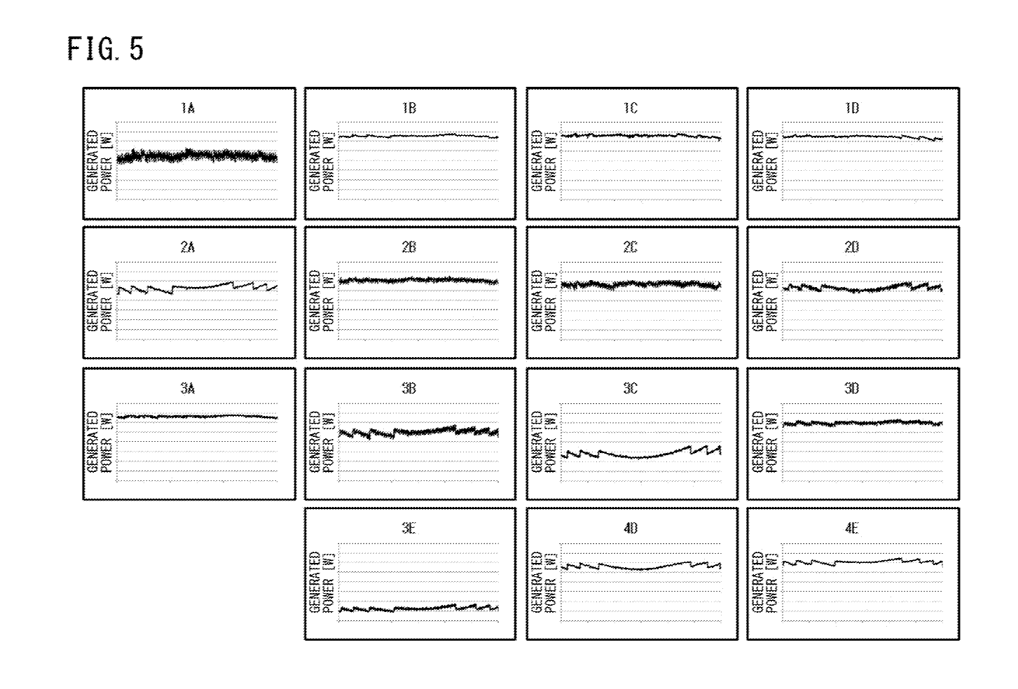

FIG. 5 shows graphs showing measured values of generated power of the 15 units of the concentrator photovoltaic apparatus 100 (1A to 4E) in a time zone (11 o'clock to 12 o'clock) around the culmination time of the sun on one day. In each graph, the horizontal axis represents time, and the vertical axis represents electric power. What to be focused on here is not the differences in generated powers among the units, but the characteristics of change included in each waveform.

Specifically, many waveforms include sawtooth-like stepped portions (jaggy portions) showing mechanical changes, and there observed are two types of change, i.e., change repeated in a short cycle, and change repeated in a relatively long cycle. The cause of the change is tracking deviation. That is, when there is no tracking deviation, no large change occurs in generated power before and after operation (tracking operation) of the stepping motor, but when there is tracking deviation, a large change is caused in generated power before and after operation of the stepping motor. Thus, it is considered that the trace of the operation of the stepping motor appears as a relatively large change in generated power.

Since FIG. 5 is the graphs with respect to the time around the culmination time, there is least change in the elevation in the day. Therefore, the longer cycle (2-5 minute cycle) is caused by tracking deviation in the elevation. The shorter cycle (20-60 second cycle) is caused by tracking deviation in the azimuth. However, in a time zone other than that around the culmination time, in some cases, change in a relatively short cycle appears also in the elevation.

<<Example of Characteristic Change Pattern>>

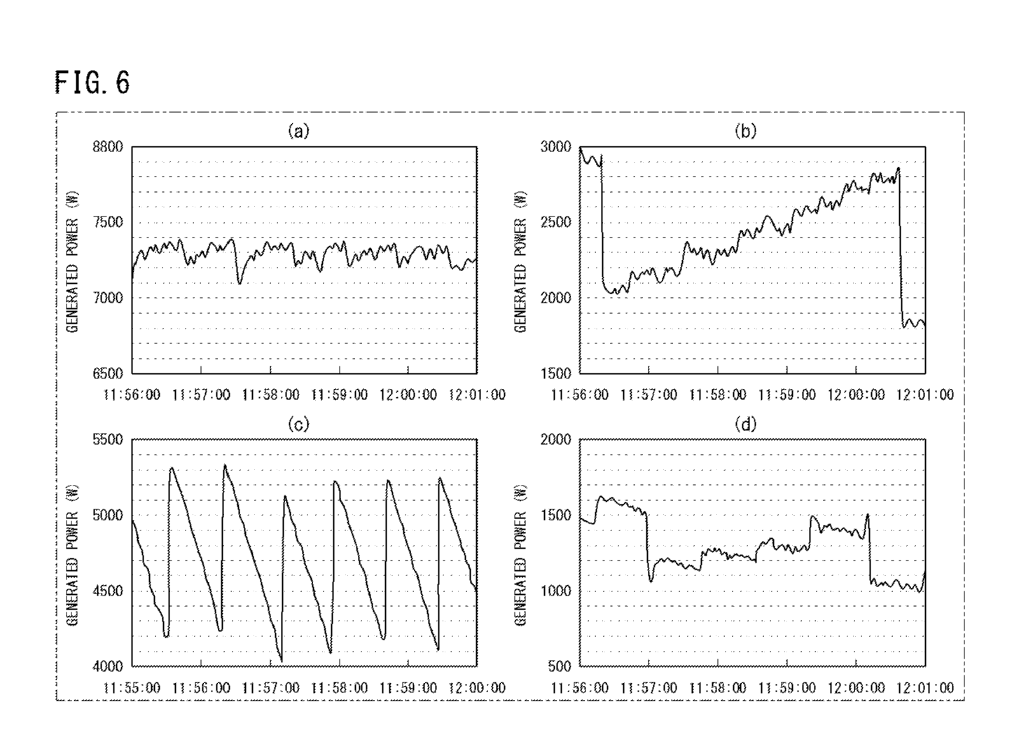

FIG. 6 shows four graphs representing extracted characteristic change patterns of waveforms. In each graph, the horizontal axis represents time and the vertical axis represents generated power. In pattern (a) at the upper left, the magnitude of change in generated power is about 300 W at maximum (about 4% of the entirety), the tracking deviation is small enough to be allowed, and thus, this is a stable state in which good tracking operation is being performed. In this case, even if a relatively conspicuous change in generated power which seems to be a result of tracking operation performed by the stepping motor is focused, the amount of change in generated power before and after execution of the tracking operation is small.

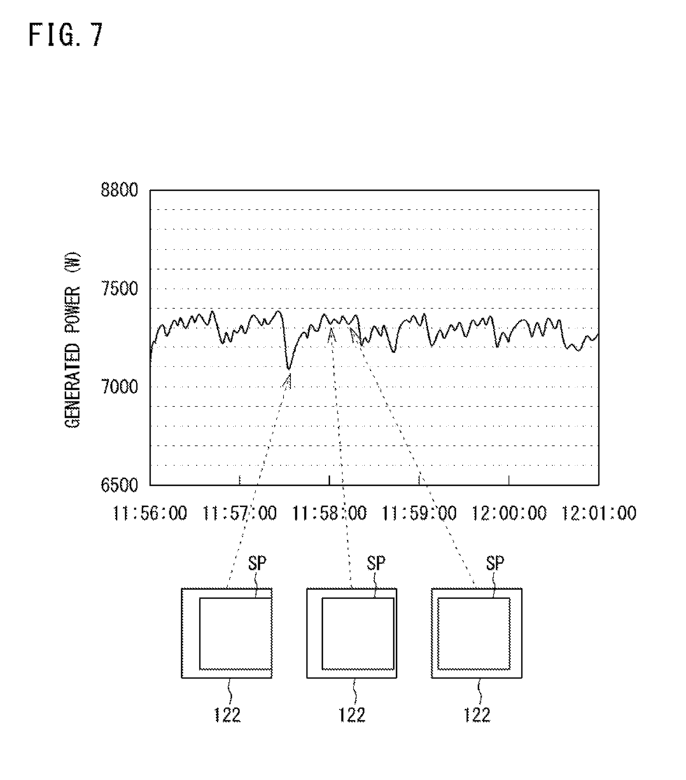

FIG. 7 shows the graph of pattern (a) in FIG. 6 and perspective charts each showing a position where a concentration spot SP is formed on the power generating element 122. In addition, broken lines show relationship between the positions on the graph and the perspective charts. As shown, in the perspective chart at the left end, the concentration spot SP is slightly off the power generating element 122, but this is a substantially good state as a whole. That is, in such a case, there is practically no tracking deviation, and thus there is no need to make correction.

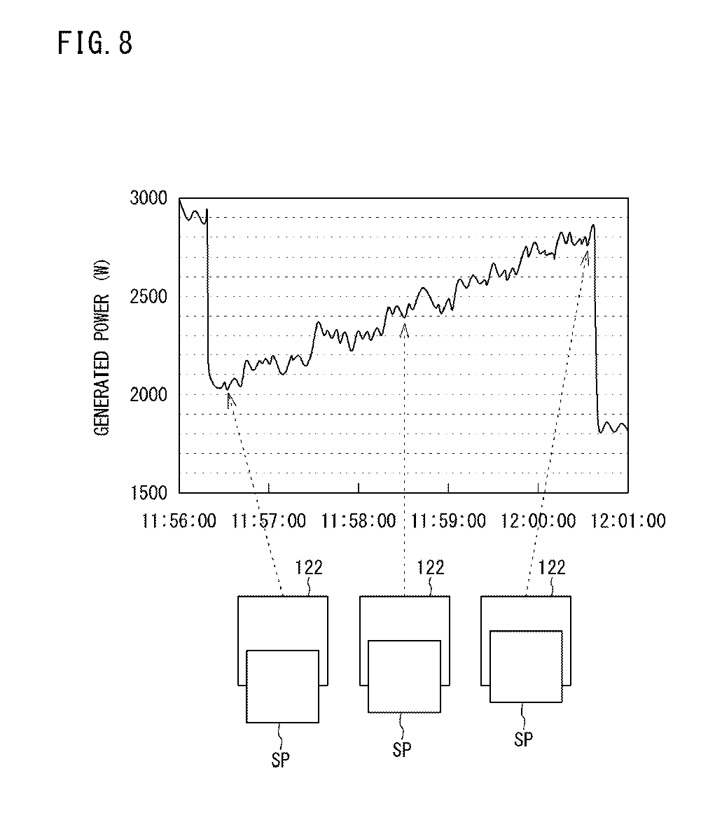

With reference back to FIG. 6, in pattern (b) at the upper right, between 11 o'clock 56 minutes and 11 o'clock 57 minutes, and between 12 o'clock 0 minutes and 12 o'clock 1 minute, large changes are occurring, and this is repeated in a long cycle of about four minutes. This is a trace of operation of the stepping motor with deviation occurring in tracking in the elevation. FIG. 8 shows the graph of pattern (b) in FIG. 6 and perspective charts each showing a position where the concentration spot SP is formed on the power generating element 122. In addition, broken lines show relationship between the positions on the graph and the perspective charts.

As shown in FIG. 8, in the perspective chart at the left end, the concentration spot SP is greatly off the power generating element 122. Thereafter, the concentration spot SP gradually enters the area of the power generating element 122, but upon operation of the stepping motor, the concentration spot SP comes to be greatly off again. Then, this is repeated. Therefore, in such a case, it is necessary to correct tracking deviation in the elevation. Moreover, in this case, the change pattern is composed of repetition of large changes and small changes therebetween. Between a large change and the next large change, generated power shows an increasing tendency, and at the operation of the stepping motor, the change in generated power shows a decrease. Such a change pattern indicates that angle deviation is in an advancing direction. It should be noted that the magnitude of smaller changes is as small as about 200 W (not higher than 10% of the entirety) at maximum, and the smaller changes can be regarded as fluctuation components, and thus are not the target for correction.

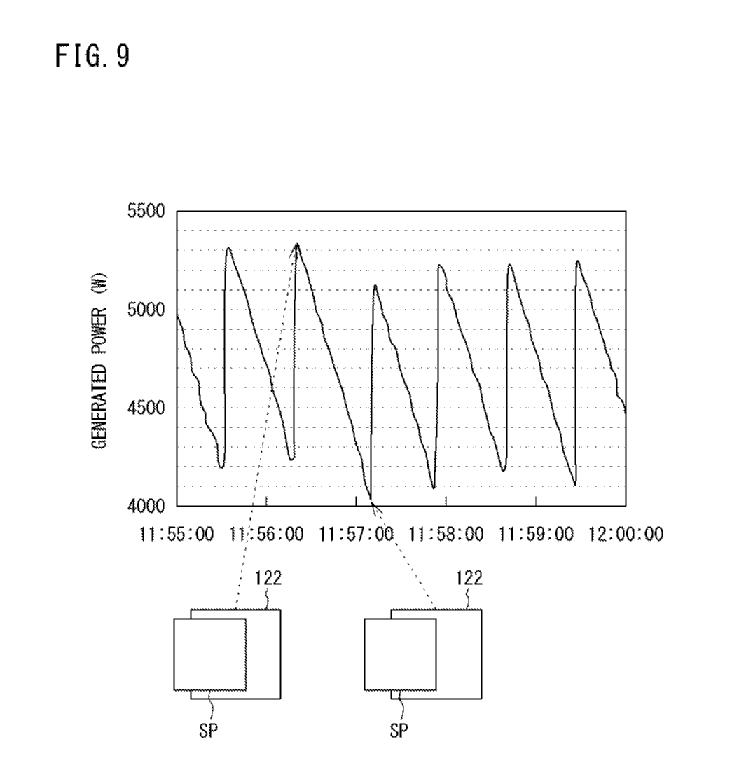

With reference back to FIG. 6, pattern (c) at the lower left, large changes are occurring in a 20-30 second cycle. This is a trace of operation of the stepping motor with deviation occurring in the azimuth. FIG. 9 shows the graph of pattern (c) in FIG. 6 and perspective charts each showing a position where the concentration spot SP is formed on the power generating element 122. In addition, broken lines show relationship between the positions on the graph and the perspective charts.

The perspective chart on the left side in FIG. 9 shows a state immediately after operation of the stepping motor, and the concentration spot SP is relatively well enough in the area of the power generating element 122. From this point, in accordance with movement of the sun in the azimuth, generated power gradually decreases, resulting in the state of the perspective chart on the right side, and again, the stepping motor operates. Then, this is repeated. Therefore, in such a case, it is necessary to correct tracking deviation in the azimuth. Moreover, in this case, the change having a substantially constant slope between large changes shows a decreasing tendency, and at the operation of the stepping motor, the change in generated power shows an increase. Such a change pattern indicates that the angle deviation is in a delay direction.

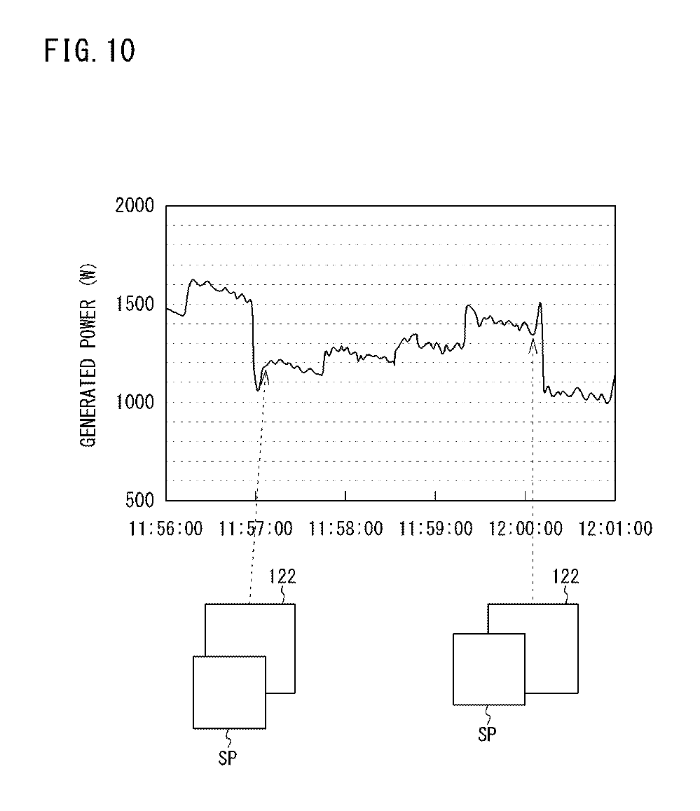

With reference back to FIG. 6, pattern (d) at the lower right is a mixed type of patterns (b) and (c). That is, here, deviation is occurring both in tracking in the azimuth and tracking in the elevation. FIG. 10 shows the graph of pattern (d) in FIG. 6 and perspective charts each showing a position where the concentration spot SP is formed on the power generating element 122. In addition, broken lines show relationship between the positions on the graph and the perspective charts.

As shown in FIG. 10, in both the perspective chart on the left side and the perspective chart on the right side, the concentration spot SP is relatively greatly off the area of the power generating element 122 (however, in the right perspective chart, the degree of being off is slightly smaller). Therefore, in such a case, it is necessary to correct tracking deviation in the azimuth and tracking deviation in the elevation. Between the large change around 11 o'clock 57 minutes and the next large change around 12 o'clock 10 seconds, generated power shows an increasing tendency as a whole, and the change at operation of the stepping motor corresponding to each large change shows a decrease. This occurs in a long cycle of about three minutes.

Moreover, between medium changes occurring at around 11 o'clock 56 minutes 15 seconds, around 11 o'clock 57 minutes 02 seconds, around 11 o'clock 57 minutes 48 seconds, around 11 o'clock 58 minutes 34 seconds, and around 11 o'clock 59 minutes 20 seconds, generated power shows a decreasing tendency and the change at operation of the stepping motor corresponding to each medium change shows an increase. The medium change occurs in an about 46-second cycle. The former corresponds to deviation in the elevation, and the latter corresponds to deviation in the azimuth. It should be noted that small changes whose amount of change is less than 100 W (not higher than 10% of the entirety) can be regarded as fluctuation components, and thus are not the target for correction.

<<Summary of Change Pattern>>

As described above, it has been found that information regarding tracking deviation is included in a change pattern repeatedly occurring in temporal change in generated power. When there is no indication (pattern (a)) of tracking deviation in the change pattern, tracking is being performed normally. If there is tracking deviation that should be corrected as in the case of (b), (c), and (d), the amount of change in generated power before and after execution of tracking operation clearly increases compared with that in the case of (a).

Therefore, a threshold is set with respect to the amount of change in generated power before and after execution of tracking operation, and then, if the amount of change is smaller than the threshold, it is possible to determine that there is no tracking deviation or that there is tracking deviation but the deviation need not be corrected, and if the amount of change is larger than the threshold, it is possible to determine that there is tracking deviation. When the amount of change is equal to the threshold, either of the above determinations may be made. For example, in the case of (a) in FIG. 6, it is sufficient to set an appropriate threshold such that the amount of change becomes smaller than the threshold, and in the case of (b), (c), and (d), it is sufficient to set an appropriate threshold such that the amount of change becomes greater than the threshold.

When the presence/absence of tracking deviation can be detected, operation of correction can further be performed, with the axis and the direction of the deviation identified. Information of the timing at which tracking operation in the elevation or the azimuth is performed and the direction of the tracking operation can be provided from the driving device of the concentrator photovoltaic panel.

<<Example of System Configuration Regarding Tracking>>

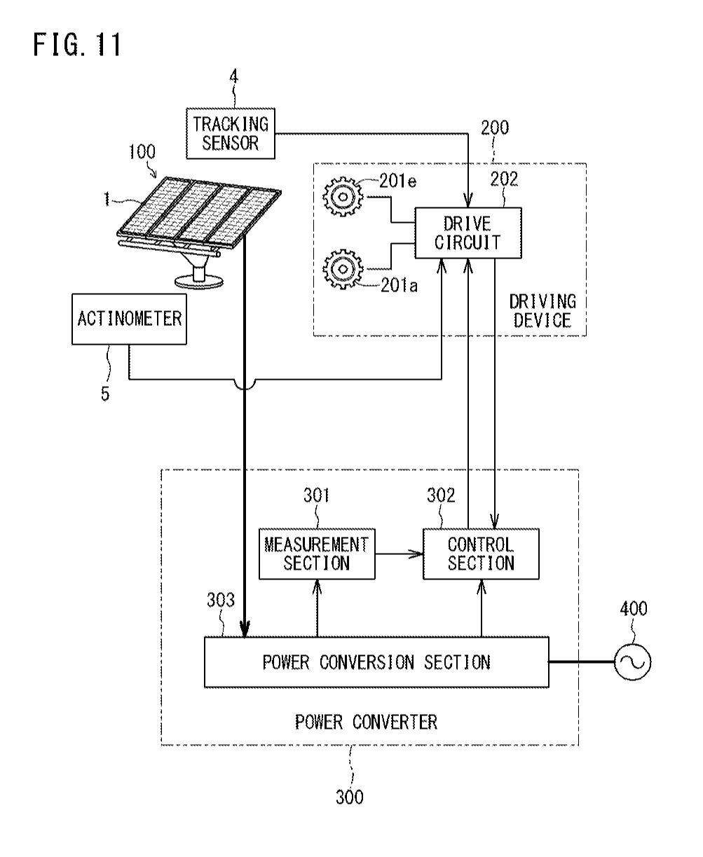

FIG. 11 is a block diagram showing one example of an electrical configuration for a concentrator photovoltaic system.

In the drawing, the concentrator photovoltaic system mainly includes the concentrator photovoltaic apparatus 100 and a power converter 300. The concentrator photovoltaic apparatus 100 includes: the concentrator photovoltaic panel 1; and a driving device 200 provided on the rear surface side of the concentrator photovoltaic panel 1, for example, for operation of tracking the sun. The driving device 200 includes: stepping motors for two axes, i.e., a stepping motor 201e for driving into the elevation direction, and a stepping motor 201a for driving into the azimuth direction; and a drive circuit 202 which drives these.

It should be noted that the stepping motors are merely examples, and another power source may be used.

The concentrator photovoltaic apparatus 100 is provided with the tracking sensor 4, by utilizing vacant space or the like of the concentrator photovoltaic panel 1. The concentrator photovoltaic panel 1 is provided with the actinometer 5. In a case where the actinometer 5 is a pyrheliometer or a normal pyranometer, the actinometer 5 is provided on the concentrator photovoltaic panel 1 or in the vicinity thereof. In a case where the actinometer 5 is a horizontal pyranometer, the actinometer 5 is fixedly provided not on the panel but in the vicinity thereof. An output from the tracking sensor 4 and an output signal (solar irradiance) from the actinometer 5 are inputted to the drive circuit 202.

The drive circuit 202 has a clock function and a storage function of storing information of the latitude and the longitude indicating the installation place of the concentrator photovoltaic panel 1, for example. The azimuth and the elevation of the sun are substantially accurately known from information of the latitude and the longitude, the day, and the time. The driving device 200 causes the stepping motor 201e or 201a to periodically operate, while referring to information obtained from the tracking sensor 4, information of the latitude, the longitude, the day, and the time, and, as necessary, information of the actinometer 5, thereby to cause the concentrator photovoltaic panel 1 to perform operation of tracking the sun.

However, there are also cases where the tracking sensor 4 is not provided. In such a case, tracking operation is performed only based on the position of the sun calculated from the latitude, the longitude, the day, and the time.

The power converter 300 includes a measurement section 301, a control section 302, and a power conversion section 303. An output from the concentrator photovoltaic panel 1 is inputted to the power conversion section 303. In the power conversion section 303, maximum power point tracking (MPPT) control is performed on the output from the concentrator photovoltaic panel 1, and further, conversion from direct current to alternating current is performed, which allows interconnection between the concentrator photovoltaic system and a commercial power system 400.

Generated power of the concentrator photovoltaic panel 1 after MPPT control can be detected by the measurement section 301 having a function of measuring voltage, current, and electric power. The measurement section 301 provides the control section 302 with information of the detected amount of generated electricity (generated power or generated current). In addition, the power conversion section 303 provides the control section 302 with a signal notifying the timing at which MPPT control is performed.

As shown, for example, the measurement section 301 and the control section 302 are housed in the housing of the power converter 300, together with the power conversion section 303. Since an output from the concentrator photovoltaic panel 1 is inputted to the power converter 300 and MPPT control is also performed in the power converter 300, it is preferable to provide the measurement section 301 in the power converter 300. Also with respect to the control section 302, since the control section 302 is relevant to the measurement section 301 and the power conversion section 303, it is preferable to provide the control section 302 in the same power converter 300.

<<Operation Performed by Control Section Regarding Tracking Deviation (Tracking Deviation Detection Method and Tracking Deviation Correction Method)>>

Hereinafter, operation performed by the control section 302 will be mainly described.

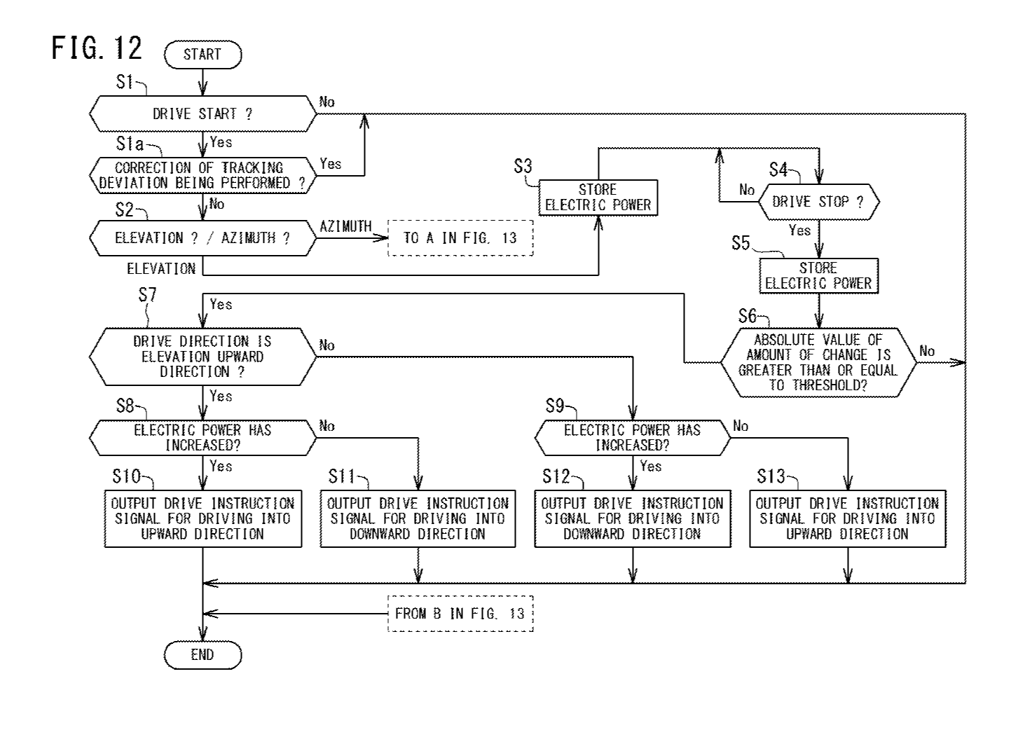

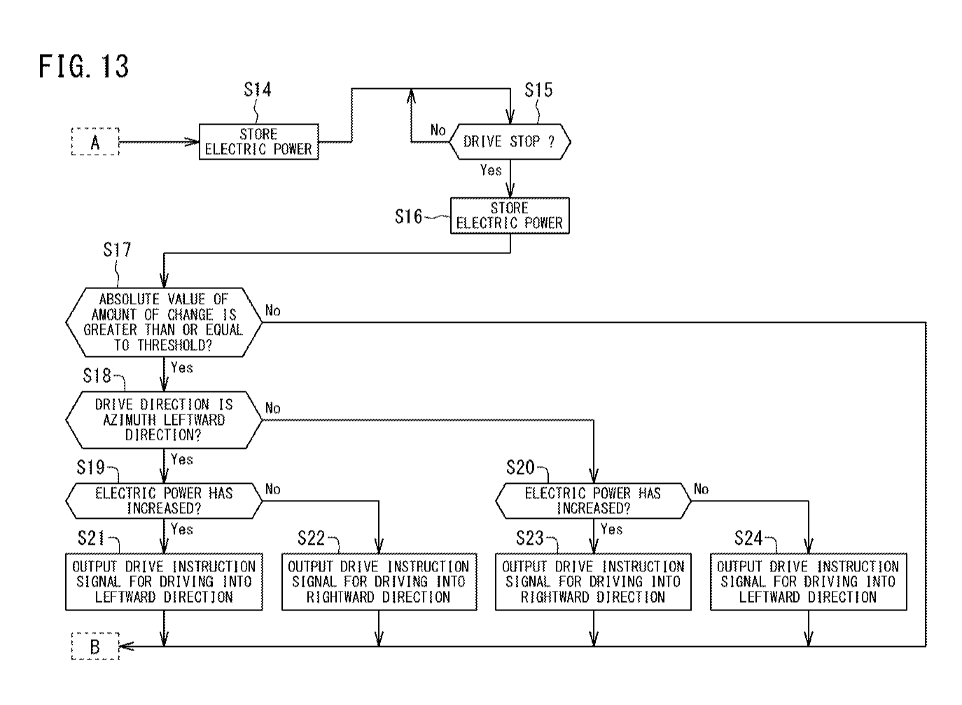

FIG. 12 and FIG. 13 show a flow chart of operation performed by the control section 302. Although FIG. 12 and FIG. 13 are drawn in two separate sheets, these two figures form one flow chart. In the following, description will be given in terms of “electric power”. However, since generated power is determined by substantially constant voltage and current which changes depending on sunshine and the like, description may be given in terms of “current”. In a more general term, it is “the amount of generated electricity”. Here, the amount of generated electricity, generated power, and generated current refer to the amount of generated electricity, generated power, and generated current obtained through MPPT control, respectively.

First, upon start of processing in FIG. 12, the control section 302 determines whether the drive circuit 202 has outputted a drive start signal for tracking operation with respect to either one of the stepping motors 201e and 201a (step S1). If the signal has not been received from the driving device 200, the processing directly ends. When the signal has been received, the control section 302 determines whether correction of tracking deviation is being performed (step S1a). If correction of tracking deviation is being performed, the processing ends. This is a step for assuredly executing one correction and then executing the next correction. If no correction is being performed, then, the control section 302 determines whether the driving is to be started in the elevation or in the azimuth (step S2). This signal is also provided from the drive circuit 202.

(Correction of Tracking Deviation in the Elevation)

If the driving has been started in the elevation, then, in step S3, the control section 302 stores the generated power at that moment. Next, the control section 302 waits for a drive stop signal to arrive from the drive circuit 202 (step S4), and when the drive stop signal has arrived, the control section 302 stores the generated power at that time (step S5). Then, with respect to one tracking operation, the control section 302 obtains the amount of change in generated power before and after the tracking operation, and determines whether or not the absolute value of that amount of change is greater than or equal to a preset threshold (step S6). If the absolute value of the amount of change is less than the threshold, there is no (practically no) tracking deviation, and thus, the processing ends.

If the absolute value of the amount of change is greater than or equal to the threshold, the control section 302 determines whether the drive direction is in the elevation upward direction (elevation downward direction) (step S7). In the case of the elevation upward direction, the control section 302 determines whether generated power has increased as a result of the tracking operation, in other words, determines the sign (plus/minus) of the change (step S8). In the case of increase, the directionality itself of the tracking operation is correct (the state after the tracking operation has become better than before the tracking operation). Thus, the control section 302 outputs, to the drive circuit 202, a drive instruction signal (correction signal) for driving into the elevation upward direction (step S10), and then the processing ends. On the contrary, in the case of decrease in step S8, the directionality itself of the tracking operation is opposite (the state after the tracking operation has become worse than before the tracking operation). Thus, the control section 302 outputs, to the drive circuit 202, a drive instruction signal (correction signal) for driving into the elevation downward direction (step S11), and then, the processing ends.

The above drive instruction signal (correction signal) is, for example, a signal for causing the stepping motor 201e to rotate by a constant correction angle. This correction angle is smaller than that made in one normal tracking operation. In a case where rotation by a constant correction angle is performed, one correction may not necessarily be able to eliminate tracking deviation, but even in such a case, a plurality of corrections can decrease the amount of deviation, in a direction along which the deviation is to be eliminated. Thus, the deviation converges in the eliminating direction.

Separately from this, it is also possible to eliminate deviation in one correction, by studying in advance the relationship between the amount of change (absolute value) and the amount of tracking deviation.

The correction amount described above also applies to the following cases.

On the other hand, in step S7, if the drive direction is the elevation downward direction (No), the control section 302 determines whether generated power has increased as a result of the tracking operation, in other words, determines the sign (plus/minus) of the change (step S9). In the case of increase, the directionality itself of the tracking operation is correct (the state after the tracking operation has become better than before the tracking operation). Thus, the control section 302 outputs, to the drive circuit 202, a drive instruction signal (correction signal) for driving into the elevation downward direction (step S12), and then, the processing ends. On the contrary, in the case of decrease in step S9, the directionality itself of the tracking operation is opposite (the state after the tracking operation has become worse than before the tracking operation). Thus, the control section 302 outputs, to the drive circuit 202, a drive instruction signal (correction signal) for driving into the elevation upward direction (step S13), and then, the processing ends.

(Correction of Tracking Deviation in the Azimuth)

In step S2, if the driving has been started in the azimuth, then, in step S14 in FIG. 13, the control section 302 stores the generated power at that moment. Next, the control section 302 waits for a drive stop signal to arrive from the drive circuit 202 (step S15), and when the drive stop signal has arrived, the control section 302 stores the generated power at that time (step S16). Then, with respect to one tracking operation, the control section 302 obtains the amount of change in generated power before and after the tracking operation, and determines whether or not the absolute value of that amount of change is greater than or equal to a preset threshold (step S17). If the absolute value of the amount of change is less than the threshold, there is no (practically no) tracking deviation, and thus, the processing ends.

If the absolute value of the amount of change is greater than or equal to the threshold, the control section 302 determines whether the drive direction is in the azimuth leftward direction (azimuth rightward direction) (step S18). In the case of the azimuth leftward direction, the control section 302 determines whether generated power has increased as a result of the tracking operation, in other words, determines the sign (plus/minus) of the change (step S19). In the case of increase, the directionality itself of the tracking operation is correct (the state after the tracking operation has become better than before the tracking operation). Thus, the control section 302 outputs, to the drive circuit 202, a drive instruction signal (correction signal) for driving into the azimuth leftward direction (step S21), and then, the processing ends. On the other hand, in the case of decrease in step S19, the directionality itself of the tracking operation is opposite (the state after the tracking operation has become worse than before the tracking operation). Thus, the control section 302 outputs, to the drive circuit 202, a drive instruction signal (correction signal) for driving into the azimuth rightward direction (step S22), and then, the processing ends.

On the other hand, in step S18, if the drive direction is in the azimuth rightward direction (No), the control section 302 determines whether generated power has increased as a result of the tracking operation, in other words, determines the sign (plus/minus) of the change (step S20). In the case of increase, the directionality itself of the tracking operation is correct (the state after the tracking operation has become better than before the tracking operation). Thus, the control section 302 outputs, to the drive circuit 202, a drive instruction signal (correction signal) for driving into the azimuth rightward direction (step S23), and then, the processing ends. On the contrary, in the case of decrease in step S20, the directionality itself of the tracking operation is opposite (the state after the tracking operation has become worse than before the tracking operation). Thus, the control section 302 outputs, to the drive circuit 202, a drive instruction signal (correction signal) for driving into the azimuth leftward direction (step S24), and then, the processing ends.

It should be noted that, different from tracking in the elevation, tracking in the azimuth is usually performed in either one of leftward direction and rightward direction, but depending on the posture of the concentrator photovoltaic panel 1 stopped during night time, there are cases where tracking in the azimuth at the time of activation first in the morning is made in the opposite direction of the movement of the sun.

(Timing of Control Regarding Tracking Deviation)

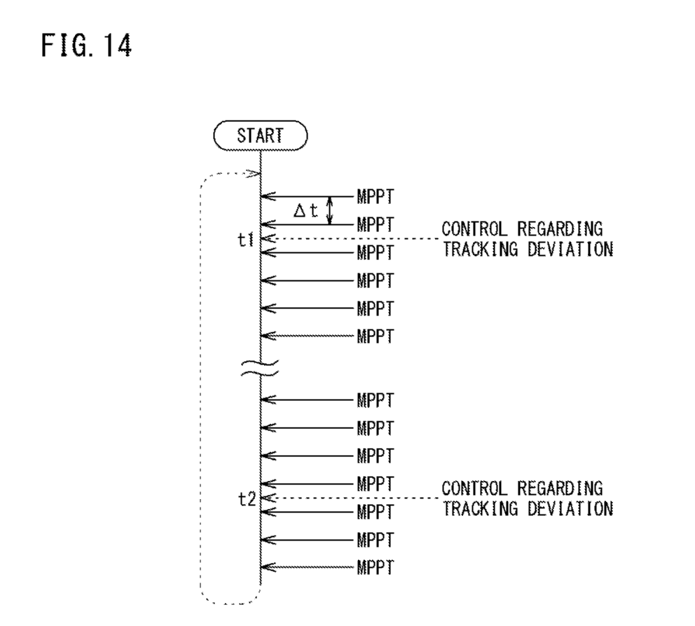

FIG. 14 shows one example of execution timings of the MPPT control performed in the power conversion section 303 and the control regarding tracking deviation performed by the control section 302 (FIG. 12, FIG. 13). The MPPT control is executed in a constant cycle t (t is 1 msec to 1 sec, for example). In order to more accurately measure generated power having been subjected to the MPPT control, it is preferable to perform control regarding tracking deviation, after one MPPT control has ended, in other words, within a cycle Δt by utilizing the period between MPPT controls. As described above, the control regarding tracking deviation requires storing generated power at drive start, storing generated power at drive stop, and correction processing. Therefore, while referring to the timings of the MPPT control received from the power conversion section 303, the control section 302 performs, at a time t1, storing generated power at drive start; and performs, at a time t2, storing generated power at drive stop and correction processing, for example.

(Independency of Processing)

It should be noted that the processing regarding tracking deviation in the above embodiment includes: (a) determining the presence/absence of tracking deviation that should be corrected; and (b) determining the axis and directionality in which the tracking deviation should be corrected, and based on the determined axis and directionality in which the correction should be made, providing the driving device 200 with an instruction to make the correction. However, both of (a) and (b) are not always required to realize a system or a method. Executing only (a) is also meaningful in that it enables easy and accurate determination as to whether there is tracking deviation that should be corrected.

(Correction Amount Made in One Correction)

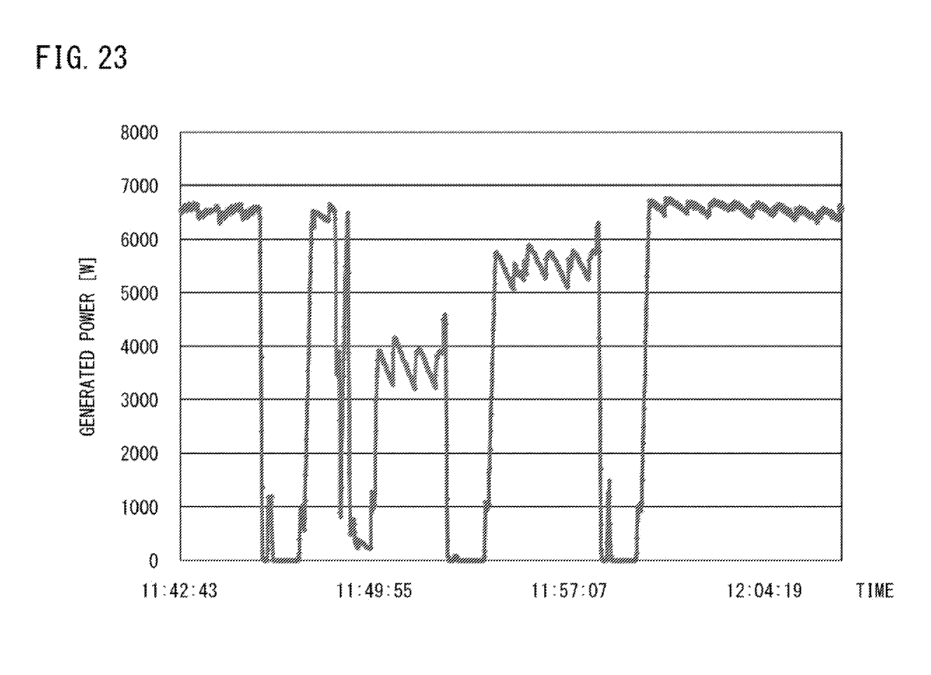

The “predetermined amount” made in one correction can be increased or decreased as necessary. FIG. 23 is a graph showing the outline of change in generated power obtained through correction. In the drawing, when change in generated power on and after 11 o'clock 49 minutes 55 seconds is focused, generated power has increased in two steps. This is the result of two corrections. When correction is made, generated power increases, and the amount of change at the time of operation of the stepping motor (the magnitude of small up-down change) becomes small. Therefore, if a correction amount in accordance with the amount of change (absolute value) is selected, it is possible to make correction such that one correction increases generated power not in two steps but in one step, from about 3200 W-4200 W to around 6500 W. That is, if the driving device is provided with an instruction to make correction based on a correction amount which changes depending on the magnitude of the absolute value of the amount of change, faster correction is enabled than in a case where correction by a constant amount is performed.

<<Summary of Control Regarding Tracking Deviation>>

In the above concentrator photovoltaic system (or the tracking deviation detection method, or the tracking deviation correction method), based on the finding that the amount of change in the amount of generated electricity before and after execution of tracking operation increases in accordance with increase of tracking deviation, it is possible to determine the presence/absence of tracking deviation that should be corrected, by comparing the absolute value of the amount of change with a threshold, for example. Since the amount of the change is that in the amount of generated electricity before and after tracking operation performed in a short time, it is less likely to be affected by the ambient brightness at that time. That is, irrespective of the state of solar radiation, it is possible to easily and accurately determine whether there is tracking deviation that should be corrected.

Moreover, when the driving device 200 has caused tracking operation to be performed, in a case where it has been determined that there is tracking deviation that should be corrected, and then, based on the axis (elevation/azimuth) in which the tracking operation has been performed, the directionality (upward/downward, leftward/rightward) of the tracking operation in the axis, and the sign (plus:increase/minus:decrease) of the change, it is possible to determine the axis and directionality in which the tracking deviation should be corrected. Then, in accordance with the determined axis and directionality in which the correction should be made, it is possible to provide an instruction to make correction by a predetermined amount, from the control section 302 to the driving device 200.

In this manner, it is possible to make correction that decreases the deviation, with the axis and directionality (orientation) determined in which the tracking deviation should be corrected.

In addition, the control section 302 is provided, from the driving device 200, with real time information of drive start and drive stop with respect to the axis in which tracking operation is performed and information about the directionality of the tracking operation. Therefore, by comparing the amount of generated electricity at the time of drive start with the amount of generated electricity at the time of drive stop based on the real time information provided from the driving device 200, it is possible to accurately obtain the amount of change. Since the control section 302 also obtains, from the driving device 200, information about the axis and directionality in which tracking operation has been performed, the control section 302 can obtain accurate information.

<<Semiconductor Integrated Circuit>>

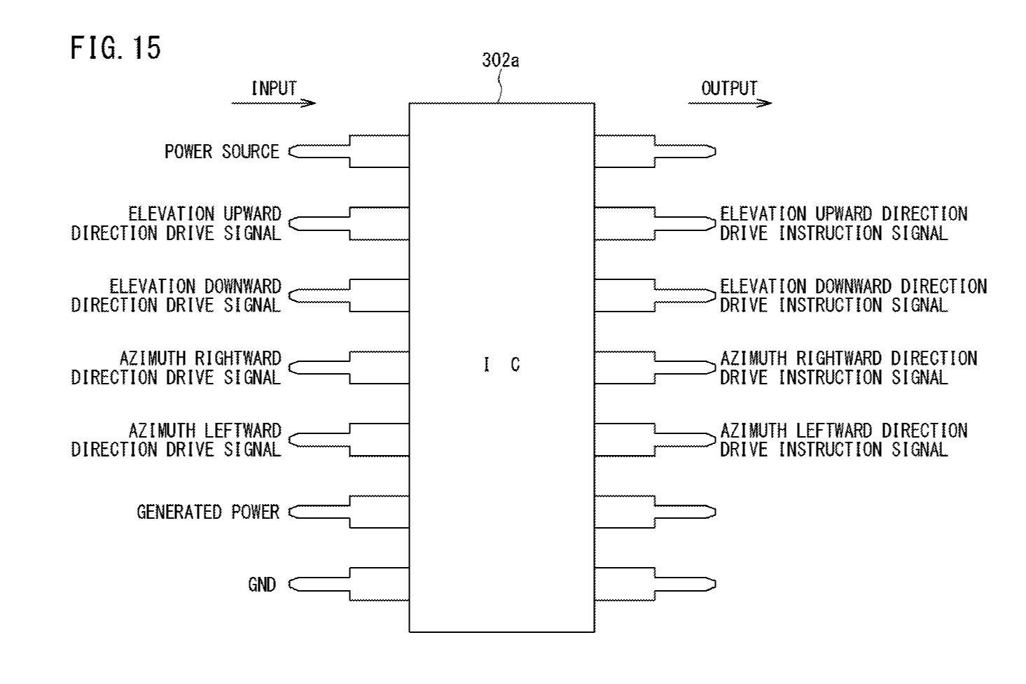

The control section 302 above can be built in a one-chip IC, for example, as a semiconductor integrated circuit, for example. FIG. 15 shows one example of a semiconductor integrated circuit 302a obtained by integrating the whole or a part of the control section 302 on a semiconductor substrate. In the drawing, seven pin inputs on the left side are, from the top in order, power source (Vcc), elevation upward direction drive signal, elevation downward direction drive signal, azimuth rightward direction drive signal, azimuth leftward direction drive signal, generated power, and GND. The elevation upward direction drive signal is outputted from the drive circuit 202. As the generated power, generated power calculated in the measurement section 301 may be converted into a signal, and the obtained signal may be inputted.

Four pin outputs on the right side of the semiconductor integrated circuit 302a in FIG. 15 are, from the top in order, elevation upward direction drive instruction signal (steps S10 and S13 in FIG. 12), elevation downward direction drive instruction signal (steps S11 and S12 in FIG. 12), azimuth rightward direction drive instruction signal (steps S22 and S23 in FIG. 13), and azimuth leftward direction drive instruction signal (steps S21 and S24 in FIG. 13).

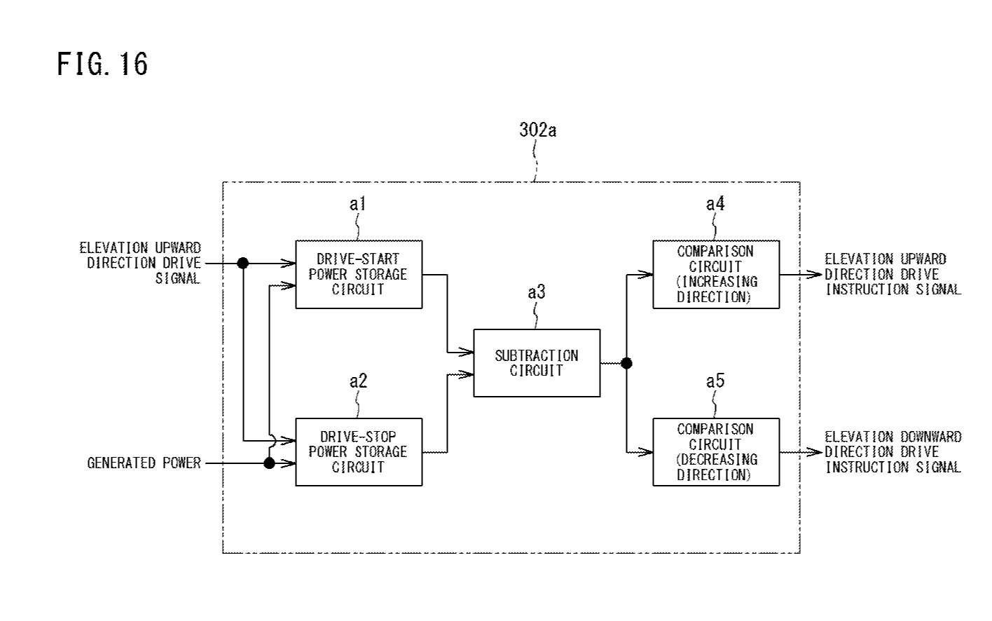

FIG. 16 is a block diagram showing one example of an internal configuration of the semiconductor integrated circuit 302a above. However, this is a figure focusing only on the elevation upward direction drive signal. The semiconductor integrated circuit 302a includes a drive-start power storage circuit a1, a drive-stop power storage circuit a2, a subtraction circuit a3, a comparison circuit a4, and a comparison circuit a5. The elevation upward direction drive signal and (the signal of) generated power are inputted to both the drive-start power storage circuit a1 and the drive-stop power storage circuit a2.

When the elevation upward direction drive signal is turned on and driving is started, the drive-start power storage circuit a1 stores the generated power at that time. When the input of the elevation upward direction drive signal is turned off and driving is stopped, the drive-stop power storage circuit a2 stores the generated power at that time. The subtraction circuit a3 obtains the difference between generated powers before and after the drive (tracking operation), and the difference, i.e., the amount of change, is compared with a threshold in the two comparison circuits a4 and a5. In the two comparison circuits a4 and a5, comparison reference values whose absolute values are the same and whose signs are opposite to each other are set, respectively. Through the comparison with these values, the elevation upward direction drive instruction signal or the elevation downward direction drive instruction signal is outputted.

In this manner, the processing in the flow chart shown in FIG. 12 and FIG. 13 can be performed by the semiconductor integrated circuit 302a, i.e. only by use of hardware.

Since the semiconductor integrated circuit 302a has necessary functions of the control section realized in the one-chip IC, production of the concentrator photovoltaic system is facilitated. Furthermore, the semiconductor integrated circuit can be produced inexpensively.

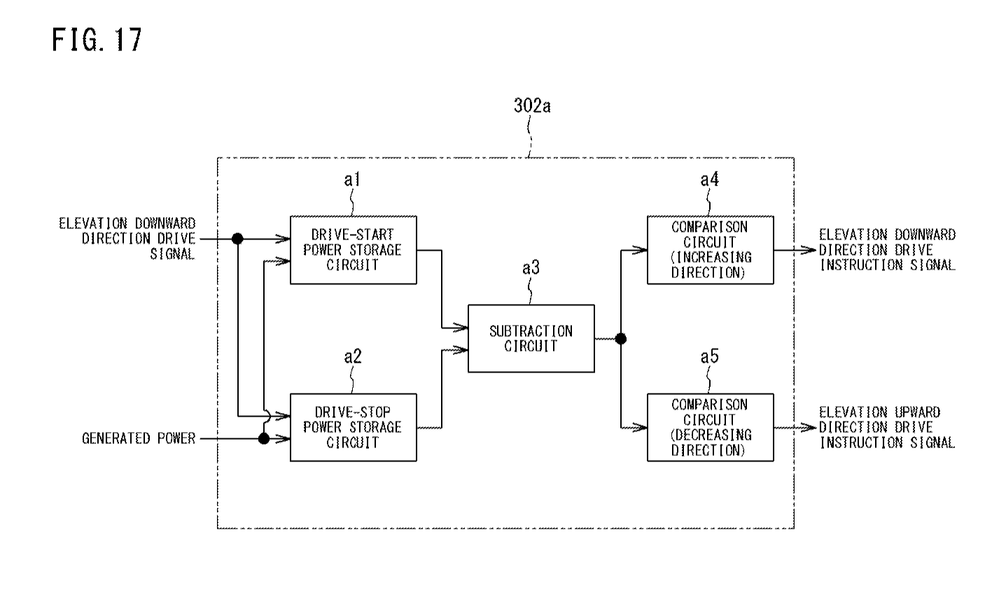

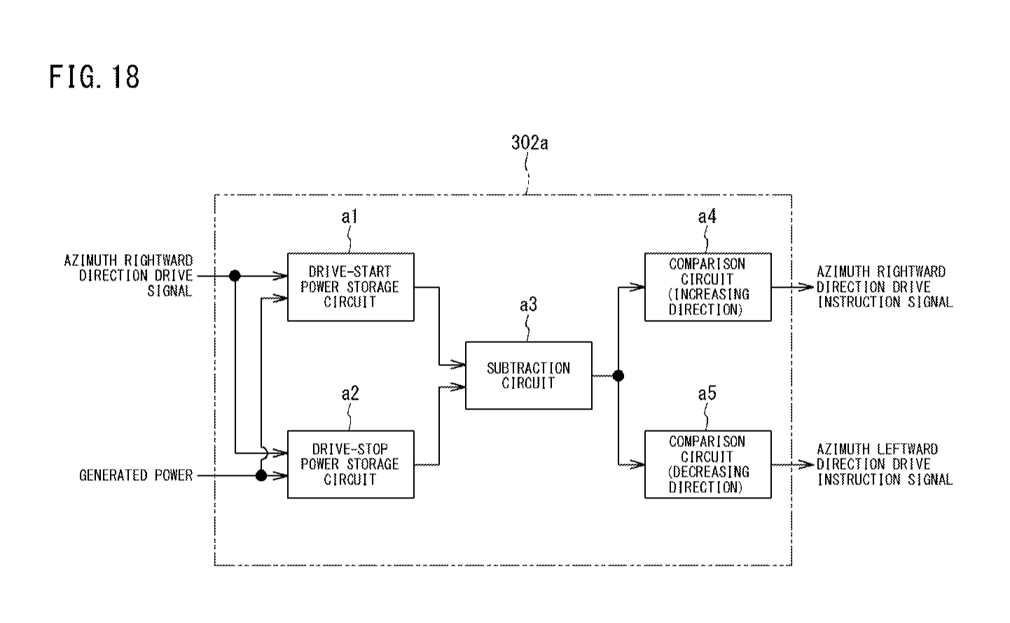

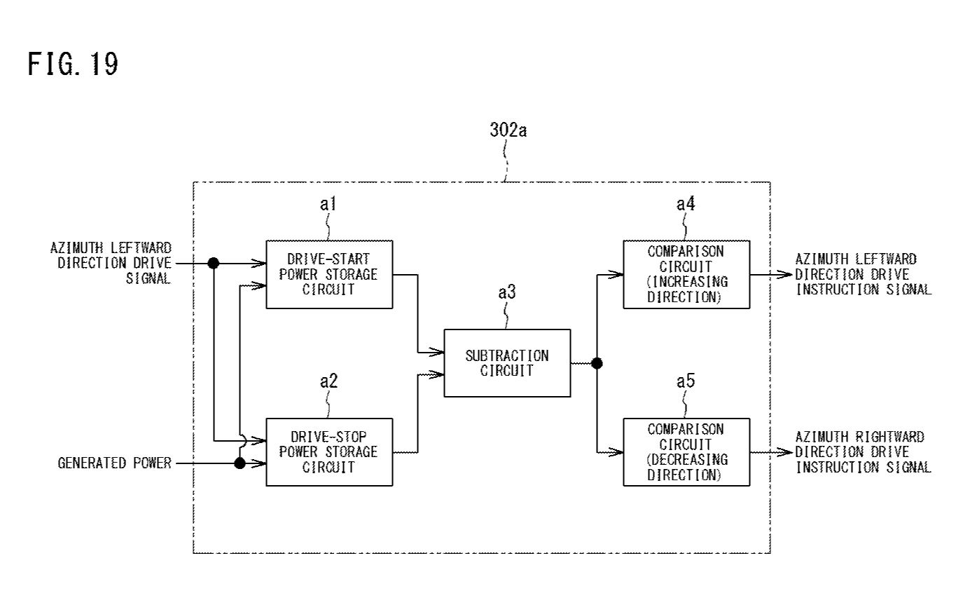

FIG. 16 is expressed only in terms of the elevation upward direction drive signal. However, other signals also have similar input and output configurations, which are respectively shown in FIG. 17 to FIG. 19. Thus, similar descriptions are not repeated here.

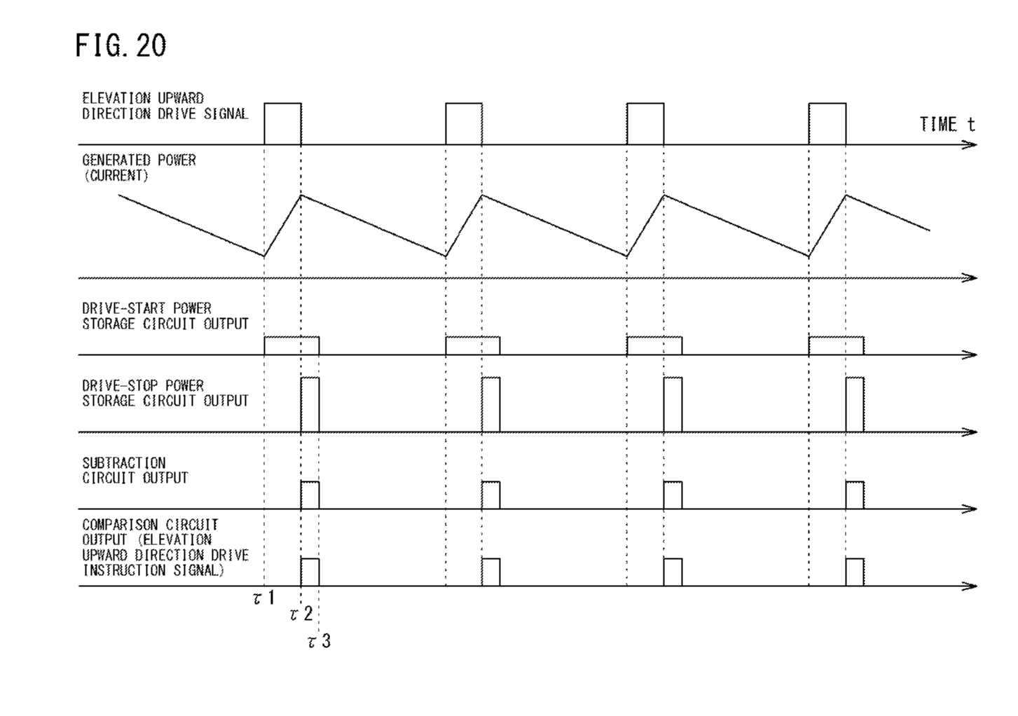

FIG. 20 is a timing chart of operation performed by the semiconductor integrated circuit 302a shown in FIG. 16. Similarly to FIG. 16, this is a figure focusing only on the operation regarding the elevation upward direction drive signal. From the top in order, there shown are elevation upward direction drive signal, generated power (or current), output from the drive-start power storage circuit a1, output from the drive-stop power storage circuit a2, output from the subtraction circuit a3, and output of elevation upward direction drive signal from the comparison circuit a4, for example.

It is assumed that, when the elevation upward direction drive signal is turned on at time T1, the stepping motor 201e (FIG. 11) is operated and tracking operation is performed, and in accordance with this, generated power has increased as shown. At the same time as the elevation upward direction drive signal is turned on, the drive-start power storage circuit a1 stores the generated power and retains it. Then, at time T2, the elevation upward direction drive signal is turned off, increase of generated power stops, and thereafter, generated power decreases gradually. At the same time as the elevation upward direction drive signal is turned off, the drive-stop power storage circuit a2 stores the generated power.

The subtraction circuit a3 calculates the difference between the two generated powers, i.e., the amount of change. Since generated power has increased, the sign of the change is plus. Through comparison with the threshold, when the amount of change is greater than the threshold, the comparison circuit a4 outputs the elevation upward direction drive instruction signal as the output from the comparison circuit a4. At time T3, the output from each circuit (a1 to a5) is reset. Thereafter, tracking operation is periodically performed, and if the state is the same, the same correction is repeated, and the tracking deviation converges in the eliminating direction.

Since other inputs and outputs (FIG. 17 to FIG. 19) are similar to those described above, description thereof is omitted here.

In the above embodiment, as the control section 302, an example has been shown which utilizes the semiconductor integrated circuit 302a mainly composed of hardware which does not require programming. However, the control section 302 may be implemented by a microcomputer or a DSP (Digital Signal Processor), and through execution of the controlling program shown in in FIG. 12 and FIG. 13, necessary functions may be realized.

In addition, the control section 302 can be integrated with a control section that controls switching and the like of the power conversion section 303.

### Second Embodiment

<<Other Examples of System Configuration Regarding Tracking>>

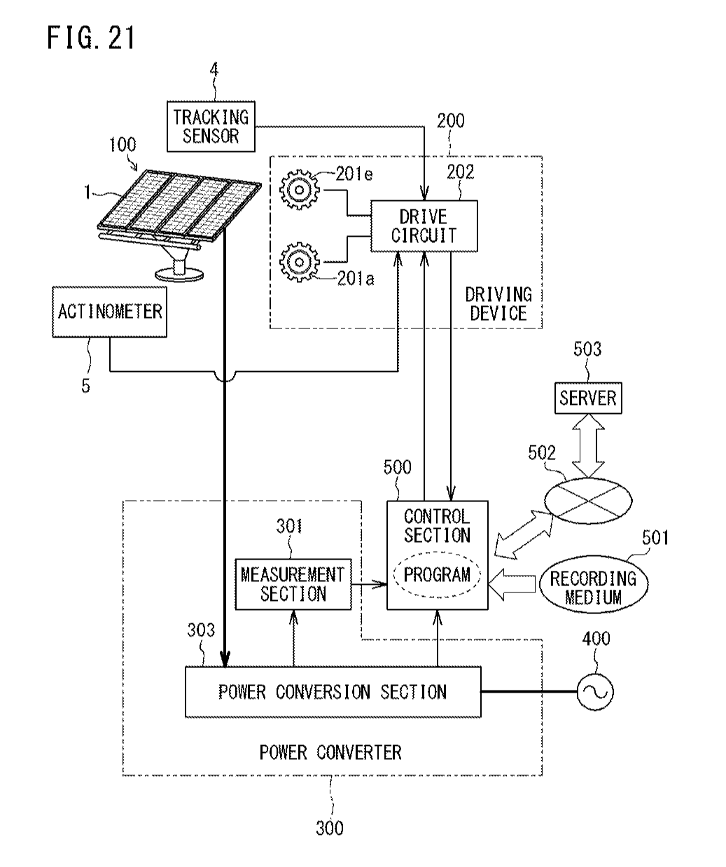

FIG. 21 is a block diagram showing one example of an electrical configuration of the concentrator photovoltaic system according to a second embodiment. The difference from FIG. 11 is that a control section 500 is provided separately from the power converter 300, and externally thereto, for example. Other configuration, operations, and effects are similar to those in the first embodiment. The functions of the control section 500 regarding tracking deviation are the same as those of the control section 302 shown in FIG. 11.

In FIG. 21, as the control section 500, a commercially available computer can be used, for example. In this case, the functions of the control section 500 are provided as a program recorded in a computer-readable recording medium (storage medium) 501, and are installed in the control section 500 which is a computer. Accordingly, the control section 500 can exhibit necessary functions. As the recording medium, for example, an optical disk, a magnetic disk, a compact memory, or the like is suitable. Further, downloading the program via a communication line 502 such as the Internet, or a form of using the program via an ASP (Application Service Provider) from a server 503 is also possible.

In the configuration shown in FIG. 21, as long as necessary signals can be received from the driving device 200 and the power converter 300, the control section 500 may be provided to the system after installation. The recording medium 501 is easy to be distributed. Thus, it is also easy to add the control section 500 to an existing concentrator photovoltaic system, and it is also easy to upgrade the system.

### Third Embodiment

<<Still Other Examples of System Configuration Regarding Tracking>>

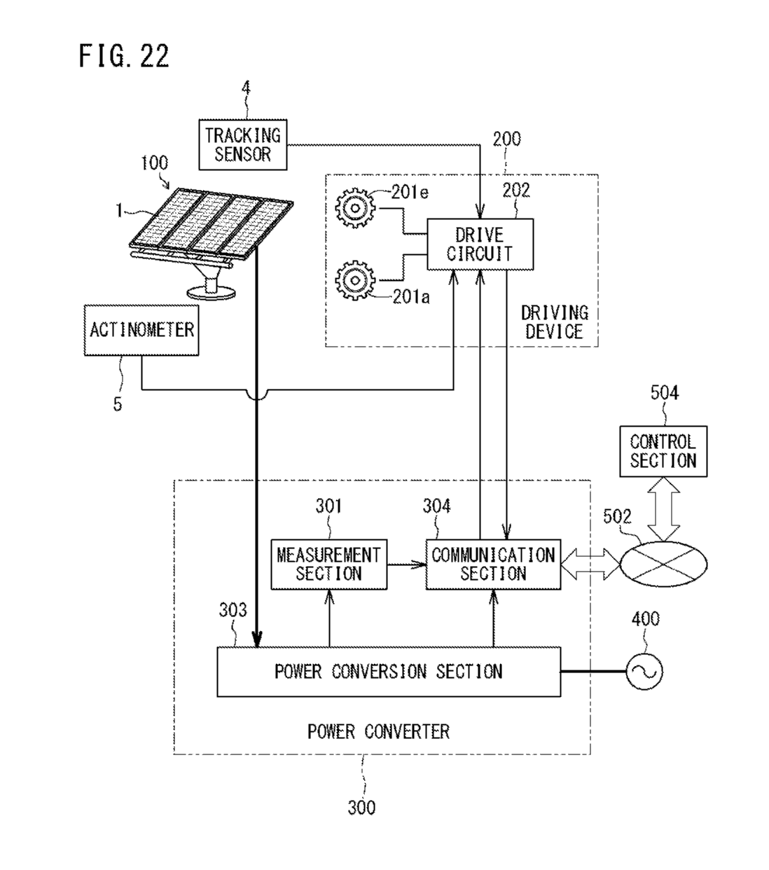

FIG. 22 is a block diagram showing one example of an electrical configuration of the concentrator photovoltaic system according to a third embodiment. The difference from FIG. 11 is that not a control section but a communication section 304 is provided inside (or outside) the power converter 300, and a control section 504 having a communication interface function is present at a remote place via the communication line 502. Other configuration, operations, and effects are similar to those in first embodiment. The functions of the control section 504 regarding tracking deviation are the same as those of the control section 302 shown in FIG. 11. The control section 504 may be a computer which executes the program, similarly to the control section 500 shown in FIG. 21.

In FIG. 22, the communication section 304 transmits and receives signals, and the control section 504 executes, at a remote place, the functions equivalent to those of the control section 302 shown in FIG. 11.

In this case, tracking deviation can be corrected through remote control via the communication line 502, and thus, this is a configuration suitable for centralized management performed from a far place.

<Others>

The manner of provision and the like of the control sections 302, 500, and 504 in the respective embodiments above can also be combined with each other (i.e., used in combination).

It should be noted that the embodiments disclosed herein are merely illustrative and not restrictive in all aspects. The scope of the present invention is defined by the scope of the claims, and is intended to include meaning equivalent to the scope of the claims and all modifications within the scope.

### REFERENCE SIGNS LIST

1 concentrator photovoltaic panel
1M concentrator photovoltaic module
3 pedestal
3a post
3b base
4 tracking sensor
5 actinometer
11 housing
11a bottom surface
11b flange portion
12 flexible printed circuit
13 primary concentrating portion
13f Fresnel lens
14 connector
100 concentrator photovoltaic apparatus
121 flexible substrate
122 power generating element
123 secondary concentrating portion
200 driving device
201e, 201a stepping motor
202 drive circuit
300 power converter
301 measurement section
302 control section
302a semiconductor integrated circuit
303 power conversion section
304 communication section
400 commercial power system
500 control section
501 recording medium
502 communication line
503 server
504 control section
a1 drive-start power storage circuit
a2 drive-stop power storage circuit
a3 subtraction circuit
a4, a5 comparison circuit
SP concentration spot

1. A concentrator photovoltaic system comprising:
a concentrator photovoltaic panel;
a driving device configured to cause the concentrator photovoltaic panel to perform periodical tracking operation with respect to the sun in two axes of azimuth and elevation;
a measurement section configured to detect generated power or generated current as an amount of generated electricity of the concentrator photovoltaic panel; and
a control section configured to obtain, when the driving device has caused the concentrator photovoltaic panel to perform tracking operation in either one of the two axes, a change in the amount of generated electricity of the concentrator photovoltaic panel before and after the tracking operation, the control section configured to determine presence/absence of tracking deviation that should be corrected, based on the change.

2. The concentrator photovoltaic system according to claim 1, wherein
when the driving device has caused the concentrator photovoltaic panel to perform tracking operation in either one of the two axes, the control section obtains an amount of change in the amount of generated electricity of the concentrator photovoltaic panel before and after the tracking operation, and determines presence/absence of tracking deviation that should be corrected, by comparing the amount of change with a predetermined threshold.

3. The concentrator photovoltaic system according to claim 1 wherein
when the driving device has caused the tracking operation to be performed, in a case where the control section has determined that there is tracking deviation that should be corrected, the control section determines an axis and directionality in which the tracking deviation should be corrected, based on the axis in which the tracking operation has been performed, directionality of the tracking operation performed in the axis, and a sign of the change, and provides the driving device with an instruction to make correction by a predetermined amount in accordance with the determined axis and directionality in which the correction should be made.

4. The concentrator photovoltaic system according to claim 2, wherein
when the driving device has caused the tracking operation to be performed, in a case where the control section has determined that there is tracking deviation that should be corrected, the control section determines an axis and directionality in which the tracking deviation should be corrected, based on the axis in which the tracking operation has been performed, directionality of the tracking operation performed in the axis, and a sign of the change, and provides the driving device with an instruction to make correction based on a correction amount which changes depending on a magnitude of an absolute value of the amount of change, in accordance with the determined axis and directionality in which the correction should be made.

5. The concentrator photovoltaic system according to claim 3, wherein
while correction of tracking deviation is being performed, the control section performs control such that detection and correction of another tracking deviation are not performed.

6. The concentrator photovoltaic system according to claim 1, wherein
the driving device provides the control section with real time information of drive start and drive stop with respect to the axis in which tracking operation is performed, and information about directionality of the tracking operation.

7. The concentrator photovoltaic system according to claim 1, wherein
the control section and the measurement section are provided in a power converter configured to convert generated power of the concentrator photovoltaic panel into alternating current power.

8. The concentrator photovoltaic system according to claim 7, wherein
by utilizing a period between maximum power point tracking controls executed by the power converter in a constant cycle, the control section executes operation regarding the tracking deviation.

9. A semiconductor integrated circuit to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel,
the semiconductor integrated circuit having a function of:
obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change.

10. The semiconductor integrated circuit according to claim 9, having a function of
determining, when having determined that there is tracking deviation that should be corrected, an axis and directionality in which the tracking deviation should be corrected, based on the axis in which the tracking operation has been performed, directionality of the tracking operation performed in the axis, and a sign of the change, and providing the driving device with an instruction to make correction in accordance with the determined axis and directionality in which the correction should be made.

11. A tracking deviation detection program to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel,
the tracking deviation detection program configured to cause a computer to realize a function of:
obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change.

12. A tracking deviation correction program to be used in a concentrator photovoltaic system, the concentrator photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel,
the tracking deviation correction program configured to cause a computer to realize:
a function of obtaining, when the driving device has caused the concentrator photovoltaic panel to perform tracking operation in either one of the two axes, a change in the amount of generated electricity of the concentrator photovoltaic panel before and after the tracking operation, and determining presence/absence of tracking deviation that should be corrected, based on the change; and
a function of determining, when having determined that there is tracking deviation that should be corrected, an axis and directionality in which the tracking deviation should be corrected, based on the axis in which the tracking operation has been performed, directionality of the tracking operation performed in the axis, and a sign of the change, and providing the driving device with an instruction to make correction in accordance with the determined axis and directionality in which the correction should be made.

13. A tracking deviation detection method performed by a control section provided in a photovoltaic system, the photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel,
the tracking deviation detection method comprising:
obtaining, when the driving device has caused the concentrator photovoltaic panel to perform tracking operation in either one of the two axes, a change in the amount of generated electricity of the concentrator photovoltaic panel before and after the tracking operation; and
determining presence/absence of tracking deviation that should be corrected, based on the change.

14. A tracking deviation correction method performed by a control section provided in a photovoltaic system, the photovoltaic system including: a concentrator photovoltaic panel; a driving device configured to cause the concentrator photovoltaic panel to perform periodical tracking operation with respect to the sun in two axes of azimuth and elevation; and a measurement section configured to detect generated power or generated current as an amount of generated electricity of the concentrator photovoltaic panel,
the tracking deviation correction method comprising:
obtaining, when the driving device has caused the concentrator photovoltaic panel to perform tracking operation in either one of the two axes, a change in the amount of generated electricity of the concentrator photovoltaic panel before and after the tracking operation;
determining presence/absence of tracking deviation that should be corrected, based on the change;
determining, when having determined that there is tracking deviation that should be corrected, an axis and directionality in which the tracking deviation should be corrected, based on the axis in which the tracking operation has been performed, directionality of the tracking operation performed in the axis, and a sign of the change; and
providing the driving device with an instruction to make correction in accordance with the axis and directionality in which the correction should be made.
